(19) United States
(12) Patent Application Publication
(10) Pub. No.: US 2014/0048311 A1
(43) Pub. Date: Feb. 20, 2014

(54) WIRED CIRCUIT BOARD

(71) Applicant: NITTO DENKO CORPORATION, Osaka (JP)

(72) Inventors: Jun ISHII, Osaka (JP); Takatoshi SAKAKURA, Osaka (JP)

(21) Appl. No.: 13/946,556

(22) Filed: Jul. 19, 2013

Related U.S. Application Data
(60) Provisional application No. 61/695,875, filed on Aug. 31, 2012.

(30) Foreign Application Priority Data
Aug. 20, 2012 (JP) 2012-181845

(51) Int. Cl. H05K 1/02

(52) U.S. Cl. CPC H05K 1/0298
USPC 174/251

(57) ABSTRACT

A wired circuit board includes a first insulating layer, a conductive pattern formed on its surface at one side in a thickness direction, and a second insulating layer formed on the surface of the first insulating layer at the one side in the thickness direction so as to cover the conductive pattern. An outer end surface of the first insulating layer in a perpendicular direction to the thickness direction is formed to be inclined outwardly gradually from the one side toward the other side in the thickness direction. An outer end surface of the second insulating layer in the perpendicular direction has an end edge at the other side in the thickness direction which is located between both end edges of the outer end surface of the first insulating layer in the perpendicular direction which are located at the one side and the other side in the thickness direction.

### CROSS-REFERENCE TO RELATED APPLICATION

The present application claims the benefit of U.S. Provisional Application No. 61/695,875, filed on Aug. 31, 2012, and also claims priority from Japanese Patent Application No. 2012-181845 filed on Aug. 20, 2012, the contents of which are herein incorporated by reference into this application.

### BACKGROUND OF THE INVENTION

1. Field of the Invention

The present invention relates to a wired circuit board, and particularly to a wired circuit board used preferably for an electronic device such as a hard disk drive.

2. Description of the Related Art

Conventionally, a wired circuit board has been known which includes an insulating base layer, a conductive pattern formed on the insulating base layer, and an insulating cover layer formed on the insulating base layer so as to cover the conductive pattern.

For example, it has been proposed that, in a suspension board including an insulating layer formed on a metal supporting board, a wiring layer formed on the insulating layer, and a cover layer formed so as to cover the wiring layer, the lower end portion of the cover layer is caused to coincide with the upper end portion of the insulating layer or positioned externally of the upper end portion of the insulating layer (see, e.g., Japanese Unexamined Patent No. 2012-14755).

### SUMMARY OF THE INVENTION

However, in the suspension board described in Japanese Unexamined Patent No. 2012-14755, when the lower end portion of the cover layer is caused to coincide with the upper end portion of the insulating layer, the cover layer and the insulating layer need to be accurately laminated.

When the cover layer and the insulating layer cannot be accurately laminated, the cover layer and the insulating layer are displaced from each other, so that the outer end portion of the lower end portion of the cover layer is located inwardly of the upper end portion of the insulating layer.

As a result, when the outer shape of the metal supporting board is formed, an etchant may enter the gap between the cover layer and the insulating layer to possibly cause delamination between the cover layer and the insulating layer.

In the case where the lower end portion of the cover layer is positioned externally of the upper end portion of the insulating layer, when the outer shape of the metal supporting board is formed, the pressure of an etchant or the like may act on the end portion of the cover layer located externally of the insulating layer to possibly cause delamination between the cover layer and the insulating layer.

It is therefore an object of the present invention to provide a wired circuit board which can allow for misalignment between a first insulating layer and a second insulating layer and also suppress delamination between the first insulating layer and the second insulating layer.

A wired circuit board of the present invention includes a first insulating layer, a conductive pattern formed on a surface of the first insulating layer at one side in a thickness direction, and a second insulating layer formed on the surface of the first insulating layer at the one side in the thickness direction so as to cover the conductive pattern. An outer end surface of the first insulating layer in a perpendicular direction which is perpendicular to the thickness direction is formed to be inclined outwardly in the perpendicular direction gradually from the one side in the thickness direction toward the other side in the thickness direction. An outer end surface of the second insulating layer in the perpendicular direction has an end edge at the other side in the thickness direction which is located between both end edges of the outer end surface of the first insulating layer in the perpendicular direction which are located at the one side and the other side in the thickness direction.

In the wired circuit board of the present invention, it is preferable that the outer end surface of the second insulating layer in the perpendicular direction is formed to be inclined outwardly in the perpendicular direction gradually from the one side in the thickness direction toward the other side in the thickness direction.

In the wired circuit board of the present invention, it is preferable that an obtuse angle formed between the outer end surface of the first insulating layer in the perpendicular direction and the outer end surface of the second insulating layer in the perpendicular direction is more than 120° and less than 180°.

In the wired circuit board of the present invention, it is preferable that an acute angle formed between an end surface of the first insulating layer at the other side in the thickness direction and the outer end surface of the first insulating layer in the perpendicular direction is not less than 20° and not more than 70°.

In the wired circuit board of the present invention, the outer end surface of the second insulating layer in the perpendicular direction has the end edge at the other side in the thickness direction which is located between the both end edges of the outer end surface of the first insulating layer in the perpendicular direction which are located at the one side and the other side in the thickness direction.

Accordingly, the misalignment of the outer end surface of the second insulating layer in the perpendicular direction with respect to the outer end surface of the first insulating layer in the perpendicular direction can be allowed for by the distance between the both end edges of the outer end surface of the first insulating film in the perpendicular direction which are located on the one side and the other side in the thickness direction.

In addition, the outer end surface of the second insulating layer in the perpendicular direction can be brought into close contact with the outer end surface of the first insulating layer in the perpendicular direction.

As a result, it is possible to suppress delamination between the first insulating layer and the second insulating layer, while allowing for the misalignment between the first insulating layer and the second insulating layer.

### BRIEF DESCRIPTION OF THE DRAWINGS

FIG. 1 is a plan view of a suspension board with circuit as an embodiment of the wired circuit board of the present invention;

FIG. 2 is a cross-sectional view along the line A-A of FIG. 1;

FIG. 3 is an enlarged view of the main portion of FIG. 2;

FIG. 4 is a cross-sectional view along the line B-B of FIG. 1;

FIG. 5 is an illustrative view illustrating a method of producing the suspension board with circuit,

FIG. 5(a) showing the step of preparing a metal supporting board,

FIG. 5(b) showing the step of applying a varnish of a photosensitive synthetic resin precursor onto the metal supporting board to form a coating and exposing the coating to light,

FIG. 5(c) showing the step of developing the exposed coating, and

FIG. 5(d) showing the step of forming a conductive pattern on an insulating base layer;

FIG. 6 is an illustrative view illustrating the method of producing the suspension board with circuit, subsequently to FIG. 5,

FIG. 6(e) showing the step of applying a varnish of a photosensitive synthetic resin precursor onto the insulating base layer to form a coating and exposing the coating to light, and

FIG. 6(f) showing the step of developing the exposed coating;

FIG. 7 is a cross-sectional view showing the case where an insulating cover layer is formed in widthwise misaligned relation to the insulating base layer; and

FIG. 8 is a scanning electron micrograph showing a cross section of the suspension board with circuit obtained in Example.

### DETAILED DESCRIPTION OF THE INVENTION

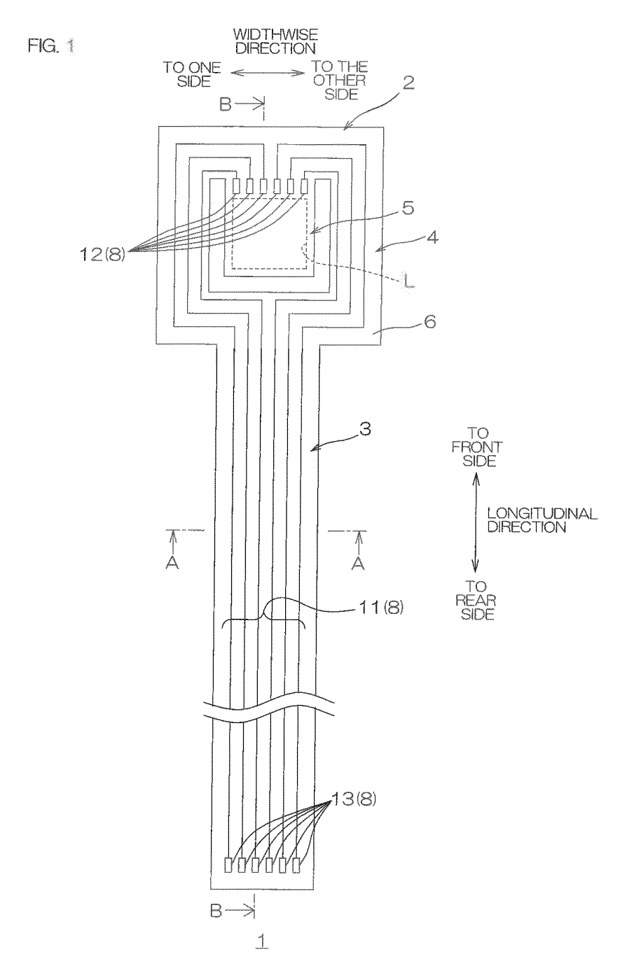

As shown in FIG. 1, a suspension board with circuit 1 is a suspension board with circuit to be mounted on the head gimbal assembly of a hard disk drive.

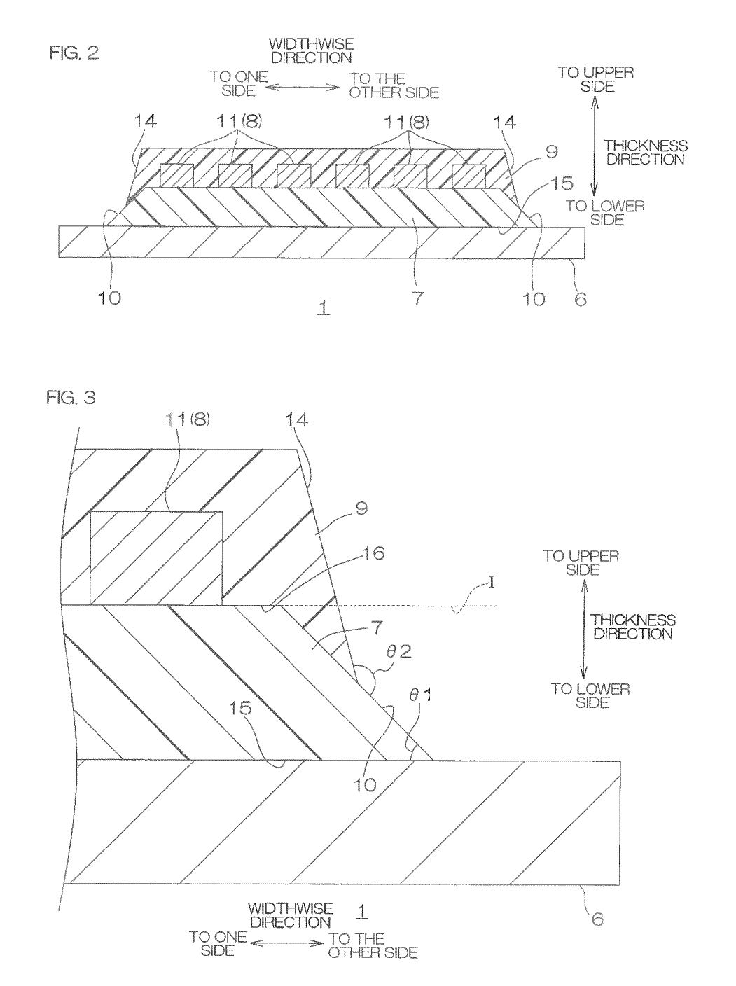

Note that, in FIG. 1, the upper side corresponds to the front side (one side in the longitudinal direction (first direction)) of the suspension board with circuit 1 and the lower side corresponds to the rear side (the other side in the longitudinal direction) of the suspension board with circuit 1. Also, in FIG. 1, the left side corresponds to one side in the widthwise direction (second direction) of the suspension board with circuit 1 and the right side corresponds to the other side in the widthwise direction of the suspension board with circuit 1. On the other hand, in FIG. 2, the upper side corresponds to the upper side (one side in the thickness direction (third direction) of the suspension board with circuit 1 and the lower side corresponds to the lower side (the other side in the thickness direction) of the suspension board with circuit 1. The longitudinal direction and the widthwise direction are perpendicular directions which are perpendicular to the thickness direction.

The suspension board with circuit 1 is formed in a generally rectangular flat-belt shape in plan view which extends in the longitudinal direction. The suspension board with circuit 1 includes a gimbal portion 2 on which a slider (not shown) including a magnetic head (not shown) is mounted, and a wiring portion 3 electrically connected to the control circuit board (not shown) of the hard disk drive.

The gimbal portion 2 is disposed on the front end portion of the suspension board with circuit 1 and formed in a generally rectangular shape in plan view. The gimbal portion 2 includes an outrigger portion 4 and a tongue portion 5.

The outrigger portion 4 is formed in a generally rectangular frame shape so as to form the outer periphery of the gimbal portion 2.

The tongue portion 5 is disposed inwardly (widthwise inwardly and longitudinally inwardly) of the outrigger portion 4. The tongue portion 5 is formed in a generally rectangular shape in plan view so as to rearwardly extend continuously from the rear end edge of the front end portion of the outrigger portion 4. In the tongue portion 5, a slider mounting region L on which the slider (not shown) is mounted is defined.

The wiring portion 3 is formed in a generally rectangular flat-belt shape in plan view which rearwardly extends continuously from the widthwise middle portion of the rear end portion of the gimbal portion 2.

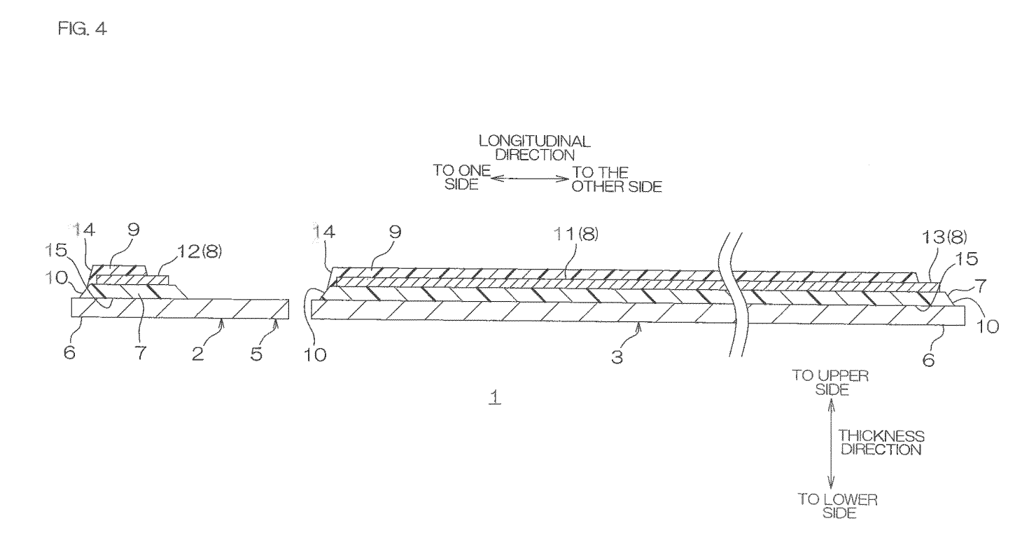

As shown in FIGS. 2 and 4, the suspension board with circuit 1 includes a metal supporting board 6, an insulating base layer 7 as an example of a first insulating layer, a conductive pattern 8, and an insulating cover layer 9 as an example of a second insulating layer.

The metal supporting board 6 is formed in a generally rectangular flat-belt shape which extends in the longitudinal direction to correspond to the outer shape of the suspension board with circuit 1 (see FIG. 1).

The insulating base layer 7 is formed on the portion of the upper surface of the metal supporting board 6 to be formed with the conductive pattern 8. The insulating base layer 7 is formed in a generally trapezoidal shape in cross section such that the longitudinal and widthwise lengths thereof increase in a downward direction. That is, an outer peripheral surface 10 of the insulating base layer 7 is inclined longitudinally outwardly and widthwise outwardly in the downward direction.

As shown in FIG. 1, the conductive pattern 8 is formed in a predetermined pattern over the insulating base layer 7. The conductive pattern 8 includes a plurality of (six) head-side terminals 12, a plurality of (six) control-side terminals 13, and a plurality of (six) wires 11.

The plurality of head-side terminals 12 are arranged in parallel on the front end portion of the tongue portion 5 to be widthwise spaced apart from each other. The head-side terminals 12 are each formed in a generally rectangular shape in plan view. The head-side terminals 12 are electrically connected to the magnetic head (not shown) of the slider (not shown).

The plurality of control-side terminals 13 are arranged in parallel on the rear end portion of the wiring portion 3 to be widthwise spaced apart from each other. The control-side terminals 13 are each formed in a generally rectangular shape. The control-side terminals 13 are electrically connected to a control circuit board (not shown).

The plurality of wires 11 are connected individually to the plurality of head-side terminals 12 and to the plurality of control-side terminals 13. The wires 11 are each formed in a generally rectangular shape in cross section.

The insulating cover layer 9 is formed over the insulating base layer 7 so as to cover the wires 11 and expose the head-side terminals 12 and the control-side terminals 13.

Also, as shown in FIGS. 2 and 4, the insulating cover layer 9 is formed in a generally trapezoidal shape in cross section having a longitudinal length and a widthwise length which downwardly increase so as to cover the upper half of the insulating base layer 7. That is, an outer peripheral surface 14 of the insulating cover layer 9 is inclined longitudinally outwardly and widthwise outwardly in the downward direction.

More specifically, as shown in FIG. 3, the widthwise outer end portion of the insulating cover layer 9 is located widthwise externally of the widthwise outer end portion of the upper end portion of the insulating base layer 7. The widthwise outer end portion of the insulating cover layer 9 is formed to protrude downwardly in accordance with the shape of the upper half of the outer peripheral surface 10 of the insulating base layer 7. In addition, the widthwise outer end portion of the insulating cover layer 9 is in close contact with the upper half of the outer peripheral surface 10 of the insulating base layer 7. That is, the lower end edge of the widthwise outer end surface (outer peripheral surface 14 in the widthwise direction) of the insulating cover layer 9 is located between the upper and lower end edges of the outer peripheral surface 10 of the insulating base layer 7.

As shown in FIG. 4, the longitudinal outer end portion of the insulating cover layer 9 is also located longitudinally externally of the longitudinal outer end portion of the upper end portion of the insulating base layer 7, similarly to the widthwise outer end portion thereof. The longitudinal outer end portion of the insulating cover layer 9 is formed to protrude downwardly in accordance with shape of the upper half of the outer peripheral surface 10 of the insulating base layer 7. In addition, the longitudinal outer end portion of the insulating cover layer 9 is in close contact with the upper half of the outer peripheral surface 10 of the insulating base layer 7. That is, the lower end edge of the longitudinal outer end surface (outer peripheral surface 14 in the longitudinal direction) of the insulating cover layer 9 is located between the upper and lower end edges of the outer peripheral surface 10 of the insulating base layer 7.

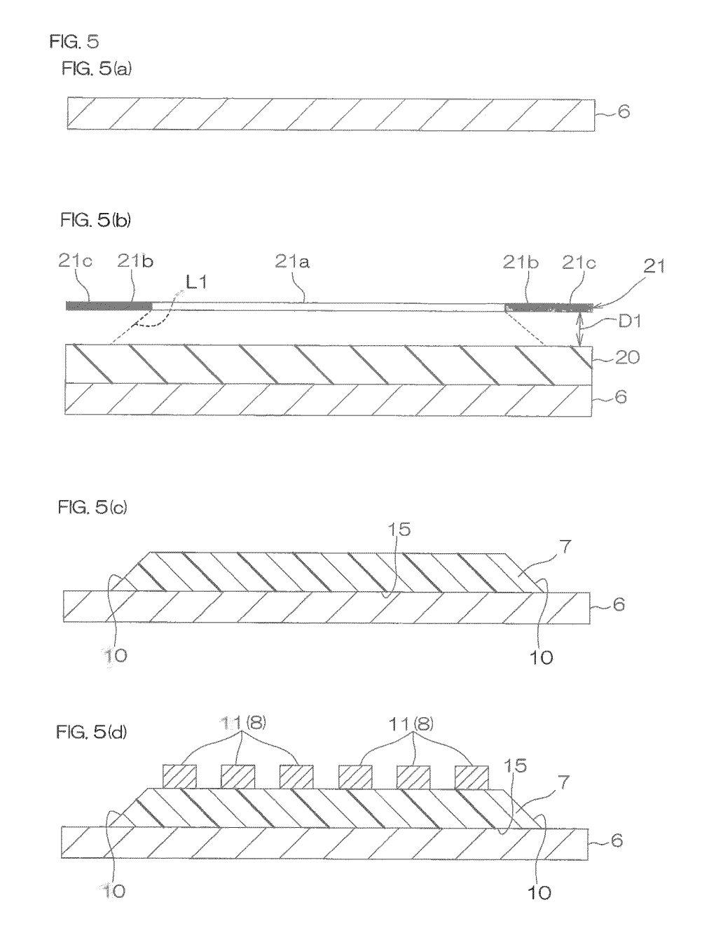

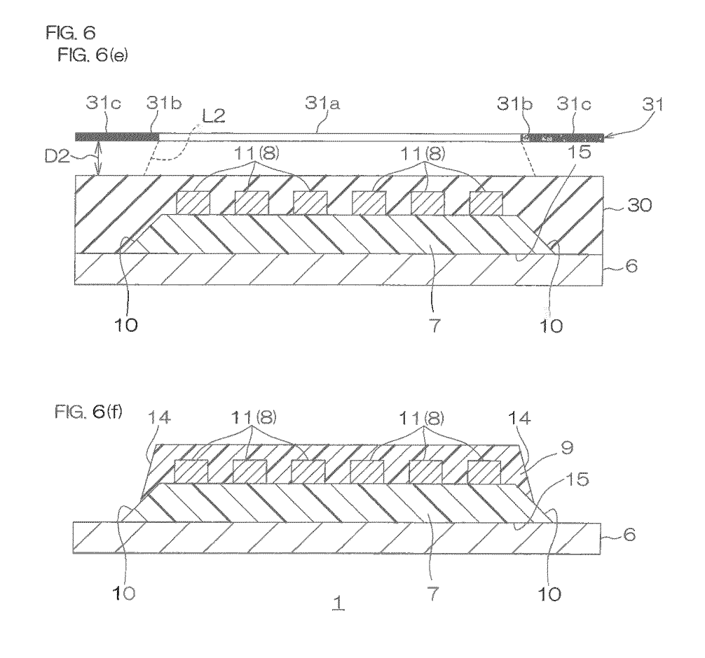

Next, referring to FIGS. 5 and 6, a method of producing the suspension board with circuit is described. Note that, in the description of the method of producing the suspension board with circuit, for the sake of convenience, a widthwise cross section (a cross section along the line A-A of FIG. 1) is used as a reference.

To produce the suspension board with circuit 1, as shown in FIG. 5(a), the metal supporting board 6 is prepared first. Note that, in the metal supporting board 6, a plurality of product formation regions (not shown) each to be formed with the suspension board with circuit 1 are defined. Each of the plurality of product formation regions (not shown) is trimmed into the outer shape of the suspension board with circuit 1 by chemical etching (wet etching) described later.

The metal supporting board 6 is formed of a metal material such as, e.g., stainless steel, a 42-alloy, aluminum, a copper-beryllium alloy, or phosphor bronze. Preferably, the metal supporting board 6 is formed of stainless steel.

The thickness of the metal supporting board 6 is in a range of, e.g., not less than 10 μm, or preferably not less than 15 μm and, e.g., not more than 50 μm, or preferably not more than 35 μm.

Next, to produce the suspension board with circuit 1, the insulating base layer 7 is formed on the upper surface of the metal supporting board 6.

The insulating base layer 7 is formed of a synthetic resin such as, e.g., polyimide, polyamide imide, acryl, polyether nitrile, polyether sulfone, polyethylene terephthalate (PET), polyethylene naphthalate, or polyvinyl chloride. Preferably, the insulating base layer 7 is formed of polyimide in terms of thermal dimensional stability or the like.

To form the insulating base layer 7, as shown in FIG. 5(b), a varnish of a photosensitive synthetic resin precursor is applied first to the upper surface of the metal supporting board 6 and then dried to form a coating 20 of the photosensitive synthetic resin precursor.

A drying temperature for the varnish is in a range of, e.g., not less than 80° C., or preferably not less than 90° C. and, e.g., not more than 200° C., or preferably not more than 170° C.

Thereafter, using a photomask 21 having a light transmitting portion 21a which transmits light and a light blocking portion 21b which blocks light, the coating 20 is exposed to light. The light transmitting portion 21a is formed in a shape corresponding to the shape of the insulating base layer 7.

Specifically, the light transmitting portion 21a is positioned to face the portion of the coating 20 in which the insulating base layer 7 is to be formed, and the light blocking portion 21b is positioned to face the portion of the coating 20 in which the insulating base layer 7 is not to be formed.

A distance D1 between the photomask 21 and the coating 20 in the thickness direction is in a range of, e.g., not less than 50 μm, or preferably not less than 100 μm and, e.g., not more than 500 μm, or preferably not more than 400 μm.

Then, the coating 20 is exposed to light via the photomask 21.

The wavelength of irradiating light L1 for the exposure is in a range of, e.g., not less than 300 nm, or preferably not less than 350 nm and, e.g., not more than 450 nm, or preferably not more than 430 nm.

As a result, the irradiating light L1 transmitted through the light transmitting portion 21a of the photomask 21 irradiates the coating 20 in such a manner as to expand in the longitudinal direction and in the widthwise direction after transmitted through the light transmitting portion 21a (see the broken line in FIG. 5(b)).

The cumulative exposure dose of the portion of the coating 20 facing the light transmitting portion 21a is in a range of, e.g., not less than 50 mJ/cm², or preferably not less than 100 mJ/cm² and, e.g., not more than 1500 mJ/cm², or preferably not more than 1000 mJ/cm².

On the other hand, the cumulative exposure dose of the portion of the coating 20 facing the light blocking portion 21b around the peripheral edge portion of the light transmitting portion 21a gradually decreases from the cumulative exposure dose of the portion of the coating 20 facing the light transmitting portion 21a with distance from the light transmitting portion 21a in a longitudinally outward direction and in a widthwise outward direction.

Here, to adjust the expansion of the irradiating light L1, the cumulative exposure dose of the portion of the coating 20 facing the light transmitting portion 21a is adjusted or the distance D1 between the photomask 21 and the coating 20 in the thickness direction is adjusted.

Specifically, by reducing the cumulative exposure dose of the portion of the coating 20 facing the light transmitting portion 21a, the expansion of the irradiating light L1 can be suppressed. Conversely, by increasing the cumulative exposure dose of the portion of the coating 20 facing the light transmitting portion 21a, the irradiating light L1 can further be expanded.

Also, by reducing the distance D1 between the photomask 21 and the coating 20 in the thickness direction, the expansion of the irradiating light L1 can be suppressed. Conversely, by increasing the distance D1 between the photomask 21 and the coating 20 in the thickness direction, the irradiating light L1 can further be expanded.

Thereafter, as shown in FIG. 5(c), the exposed coating 20 is developed.

To develop the coating 20, the exposed coating 20 is heated to be cured (insolubilized), and then developed by a known method such as a dipping method or a spraying method using, e.g., a known developer such as an alkaline developer.

A heating temperature for the coating 20 is in a range of, e.g., not less than 40° C., or preferably not less than 42° C. and, e.g., not more than 60° C., or preferably not more than 57° C.

A heating time for the coating 20 is in a range of, e.g., not less than 2 minutes, or preferably not less than 3 minutes and, e.g., not more than 10 minutes, or preferably not more than 6 minutes.

As a result, of the coating 20, the portion facing the light blocking portion 21b is removed and the portion facing the light transmitting portion 21a is formed with the insulating base layer 7. At this time, the outer peripheral surface 10 of the insulating base layer 7 is inclined longitudinally outwardly and widthwise outwardly in the downward direction.

The thickness of the insulating base layer 7 (thickness of the portion thereof facing the light transmitting portion 21a) is in range of, e.g., not less than 1 μm, or preferably not less than 3 μm and, e.g., not more than 35 μm, or preferably not more than 15 μm.

An angle θ1 between the outer peripheral surface 10 of the insulating base layer 7 and the lower surface 15 thereof is in a range of, e.g., not less than 20°, or preferably not less than 30° and, e.g., not more than 70°, or preferably not more than 60° (see FIG. 3).

Note that, when the insulating base layer 7 is formed, in the region other than the product formation regions (not shown), alignment marks made of the same material as that of the insulating base layer 7 are formed on the upper surface of the metal supporting board 6.

Next, to produce the suspension board with circuit 1, as shown in FIG. 5(d), the conductive pattern 8 is formed on the insulating base layer 7.

The conductive pattern 8 is formed of a conductive material such as, e.g., copper, nickel, gold, a solder, or an alloy thereof. Preferably, in terms of a property of reflection of light, the conductive pattern 8 is formed of copper.

To form the conductive pattern 8, a known patterning method such as, e.g., an additive method or a subtractive method is used and, preferably, the additive method is used.

Specifically, in the additive method, a conductive seed film is formed first on the surface of the metal supporting board 7 including the insulating base layer 7 by a sputtering method or the like. Then, on the surface of the conductive seed film, a plating resist is formed in a pattern reverse to the conductive pattern 8. Subsequently, on the surface of the conductive seed film on the insulating base layer 7, the conductive pattern 8 is formed by electrolytic plating. Thereafter, the plating resist and the portion of the conductive seed film where the plating resist is laminated are removed.

The thickness of the conductive pattern 8 is in a range of, e.g., not less than 3 μm, or preferably not less than 5 μm and, e.g., not more than 50 μm, or preferably not more than 20 μm. The widths of the wires 11 may be the same or different and are in a range of, e.g., not less than 5 μm, or preferably not less than 8 μm and, e.g., not more than 500 μm, or preferably not more than 200 μm. The spacings between the wires 11 adjacent to each other may be the same or different and are in a range of, e.g., not less than 5 μm, or preferably not less than 8 μm and, e.g., not more than 1000 μm, or preferably not more than 100 μm.

Next, to produce the suspension board with circuit 1, on the insulating base layer 7, the insulating cover layer 9 is formed so as to cover the conductive pattern 8.

As an insulating material for forming the insulating cover layer 9, the same insulating material as the insulating material for forming the insulating base layer 7 shown above can be used and, preferably, polyimide is used.

The insulating cover layer 9 is formed in the same manner as the insulating base layer 7 described above. First, as shown in FIG. 6(e), a varnish of a photosensitive synthetic resin precursor is applied to the upper surfaces of the metal supporting board 6, the insulating base layer 7, and the conductive pattern 8 and then dried to form a coating 30 of the photosensitive synthetic resin precursor.

A drying temperature for the varnish is in a range of, e.g., not less than 80° C., or preferably not less than 90° C. and, e.g., not more than 200° C., or preferably not more than 170° C.

Thereafter, using a photomask 31 having a light transmitting portion 31a and a light blocking portion 31b, the coating 30 is exposed to light. The light transmitting portion 31a is formed in a shape corresponding to the shape of the insulating cover layer 9.

Specifically, using the alignment marks formed on the surface of the metal supporting board 6 as a reference, the photomask 31 is caused to face the coating 30. As a result, the light transmitting portion 31a is positioned to face the portion of the coating 30 in which the insulating cover layer 9 is to be formed, and the light blocking portion 31b is positioned to face the portion of the coating 30 in which the insulating cover layer 9 is not to be formed.

A distance D2 between the photomask 31 and the coating 30 in the thickness direction is in a range of, e.g., not less than 50 μm, or preferably not less than 100 μm and, e.g., not more than 500 μm, or preferably not more than 400 μm.

Then, the coating 30 is exposed to light via the photomask 31.

The wavelength of irradiating light L2 for the exposure is in a range of, e.g., not less than 300 nm, or preferably not less than 350 nm and, e.g., not more than 450 nm, or preferably not more than 430 nm.

Then, the irradiating light L2 transmitted through the light transmitting portion 31a of the photomask 31 irradiates the coating 30 in such a manner as to expand in the longitudinal direction and in the widthwise direction after transmitted through the light transmitting portion 31a (see the broken line in FIG. 6(e)).

The cumulative exposure dose of the portion of the coating 30 facing the light transmitting portion 31a is in a range of, e.g., not less than 50 mJ/cm², or preferably not less than 100 mJ/cm² and, e.g., not more than 1500 mJ/cm², or preferably not more than 1000 mJ/cm².

On the other hand, the cumulative exposure dose of the portion of the coating 30 facing the light blocking portion 31b around the peripheral edge portion of the light transmitting portion 31a gradually decreases from the cumulative exposure dose of the portion of the coating 30 facing the light transmitting portion 31a with distance from the light transmitting portion 31a in the longitudinally outward direction and in the widthwise outward direction.

Here, to adjust the expansion of the irradiating light L2, the cumulative exposure dose of the portion of the coating 30 facing the light transmitting portion 31a is adjusted, or the distance D2 between the photomask 31 and the coating 30 in the thickness direction is adjusted.

Specifically, by reducing the cumulative exposure dose of the portion of the coating 30 facing the light transmitting portion 31a, the expansion of the irradiating light L2 can be suppressed. Conversely, by increasing the cumulative exposure dose of the portion of the coating 30 facing the light transmitting portion 31a, the irradiating light L2 can further be expanded.

Also, by reducing the distance D2 between the photomask 31 and the coating 30 in the thickness direction, the expansion of the irradiating light L2 can be suppressed. Conversely, by increasing the distance D2 between the photomask 31 and the coating 30 in the thickness direction, the irradiating light L2 can further be expanded.

Thereafter, as shown in FIG. 6(f), the exposed coating 30 is developed.

To develop the coating 30, the exposed coating 30 is heated to be cured (insolubilized), and then developed by a known method such as a dipping method or a spraying method using, e.g., a known developer such as an alkaline developer.

A heating temperature for the coating 30 is in a range of, e.g., not less than 40° C., or preferably not less than 42° C. and, e.g., not more than 60° C., or preferably not more than 57° C.

A heating time for the coating 30 is in a range of, e.g., not less than 2 minutes, or preferably not less than 3 minutes and, e.g., not more than 10 minutes, or preferably not more than 6 minutes.

As a result, of the coating 30, the portion facing the light blocking portion 31b is removed and the portion facing the light transmitting portion 31a is formed with the insulating cover layer 9. At this time, the outer peripheral surface 14 of the insulating cover layer 9 is included longitudinally outwardly and widthwise outwardly in the downward direction.

The thickness of the insulating cover layer (thickness of the portion thereof facing the light transmitting portion 31a) is in range of, e.g., not less than 1 μm, or preferably not less than 2 μm and, e.g., not more than 40 μm, or preferably not more than 20 μm.

An angle θ2 between the outer peripheral surface 14 (outer peripheral surface 14 below a virtual plane I (see FIG. 3) including the lower surface 16 of the insulating cover layer 9 in Example described later) of the insulating cover layer 9 and the outer peripheral surface 10 of the insulating base layer 7 is in a range of, e.g., more than 120°, or preferably not less than 130° and, e.g., less than 180°, or preferably not more than 170° (see FIG. 3).

Thereafter, the metal supporting board 6 is trimmed by a known etching method such as chemical etching (wet etching) to obtain the suspension board with circuit 1.

In the suspension board with circuit 1, as shown in FIG. 3, the lower end edge of the outer peripheral surface 14 of the insulating cover layer 9 is located between the upper and lower end edges of the outer peripheral surface 10 of the insulating base layer 7.

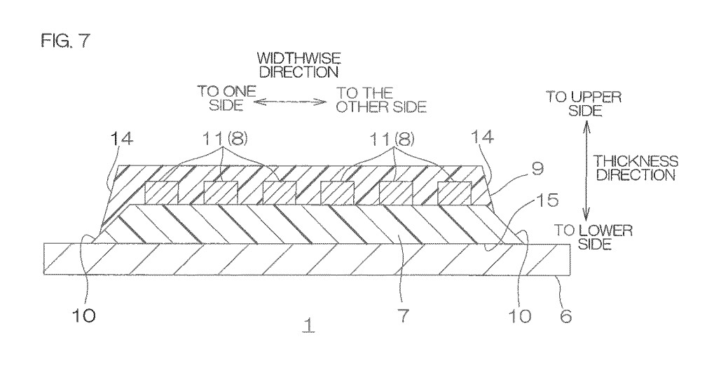

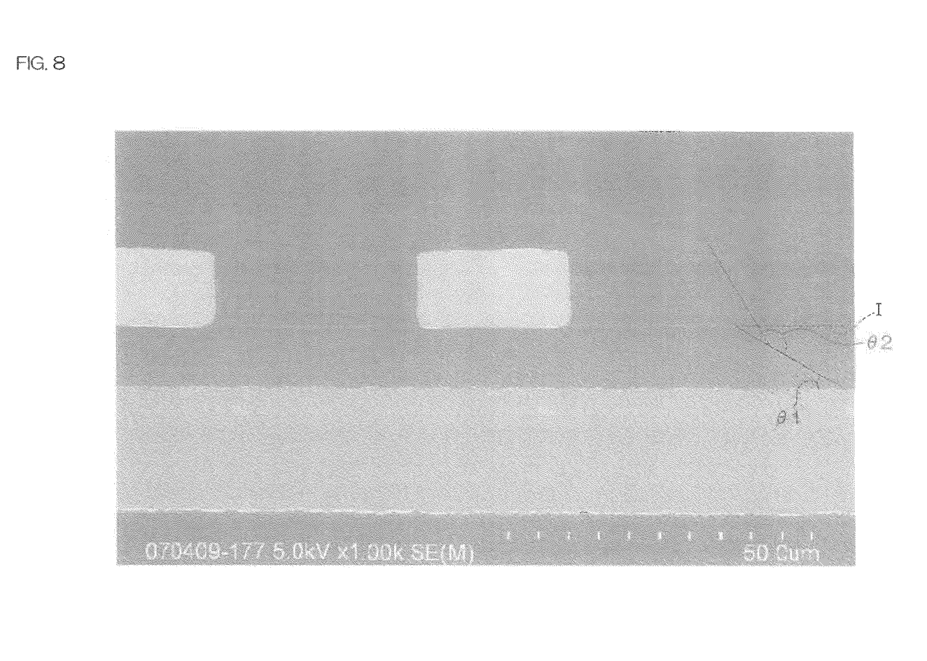

As a result, as shown in FIG. 7, even when the insulating cover layer 9 is formed in misaligned relation to the insulating base layer 7 such as when the photomask 31 (see FIG. 6(e)) for exposing the insulating cover layer 9 to light is disposed to face the alignment marks in misaligned relation thereto, the outermost wire 11 can be reliably covered.

In addition, the angle θ2 between the outer peripheral surface 14 of the insulating cover layer 9 and the outer peripheral surface 10 of the insulating base layer 7 can also be held at an obtuse angle.

That is, the misalignment of the insulating cover layer 9 with respect to the outer peripheral surface 10 of the insulating base layer 7 can be allowed for by the distance between the upper and lower end edges of the outer peripheral surface 10 of the insulating base layer 7.

Moreover, the longitudinal and widthwise outer end portions of the insulating cover layer 9 can be brought into close contact with the outer peripheral surface 10 of the insulating base layer 7.

As a result, it is possible to suppress delamination between the insulating base layer 7 and the insulating cover layer 9, while allowing for the misalignment between the insulating base layer 7 and the insulating cover layer 9.

### Example

While in the following, the present invention is described more specifically with reference to Example, the present invention is by no means limited thereby.

### Example

(Production of Suspension Board with Circuit)

A metal supporting board made of stainless steel having a thickness of 25 μm was prepared (see FIG. 5(a)).

Then, a varnish of a photosensitive polyamic acid resin was applied to a surface of the metal supporting board and dried at 100° C. to form a coating over the photosensitive polyamic acid resin (see FIG. 5(b)).

Then, a photomask having a light transmitting portion and a light blocking portion was caused to face the coating from a position 200 μm apart in the thickness direction.

Thereafter, the coating was exposed to irradiating light at a wavelength of 350 nm to 450 nm such that the cumulative exposure dose of the portion of the coating facing the light transmitting portion was 900 mJ/cm² (see FIG. 5(b)).

Then, the exposed coating was heated at 46° C. for 5 minutes to be cured (insolubilized), and then developed to form an insulating base layer (see FIG. 5(c)).

The widthwise outer surface of the insulating base layer was formed to be downwardly inclined in the widthwise outward direction.

The thickness of the insulating base layer (the thickness thereof except for the widthwise outer end portion and the longitudinal outer end portion thereof) was 5 μm.

At the same time as the insulating base layer was formed, alignment marks made of the same material as that of the insulating base layer were formed on the metal supporting board.

Then, on the surface of the insulating base layer including that of the metal supporting board, a chromium thin film having a thickness of 0.03 μm and a copper thin film having a thickness of 0.07 μm were successively formed by chromium sputtering and copper sputtering to serve as a conductive thin film. Subsequently, a plating resist in a pattern reverse to a conductive pattern was formed on the surface of the conductive film. Thereafter, on the surface of the conductive thin film exposed from the plating resist, the conductive pattern having a thickness of 10 μm was formed by electrolytic copper plating. Then, the plating resist and the portion of the conductive thin film where the plating resist was formed were removed by chemical etching to form the conductive pattern on the insulating base layer (see FIG. 5(d)).

Then, to the surfaces of the metal supporting board, the insulating base layer, and the conductive pattern, a varnish of a photosensitive polyamic acid resin was applied and dried at 100° C. to form a coating of the photosensitive polyamic acid resin (see FIG. 6(e)).

Then, using the alignment marks as a reference, a photomask having a light transmitting portion and a light blocking portion was caused to face the coating from a position 200 μm apart in the thickness direction. As a result, the outer peripheral edge of the light transmitting portion faced the coating formed over the outer peripheral surface of the insulating base layer.

Thereafter, the coating was exposed to irradiating light at a wavelength of 350 nm to 450 nm such that the cumulative exposure dose of the portion of the coating facing the light transmitting portion was 260 mJ/cm² (see FIG. 6(e)).

Then, the exposed coating was heated at 45° C. for 3 minutes to be cured (insolubilized), and then developed to form an insulating cover layer (see FIG. 6(f)).

The lower end edge of the widthwise outer end portion of the insulating cover layer was positioned between the upper and lower end edges of the widthwise outer surface (widthwise outer peripheral surface) of the insulating base layer. In addition, the widthwise outer surface of the insulating cover layer was formed to be downwardly inclined in the widthwise outward direction.

On the other hand, the lower end edge of the longitudinal outer end portion of the insulating cover layer was positioned between the upper and lower end edges of the longitudinal outer surface (longitudinal outer peripheral surface) of the insulating base layer. In addition, the longitudinal outer surface of the insulating cover layer was formed to be downwardly inclined in the longitudinally outward direction.

The thickness of the insulating cover layer (the thickness thereof except for the widthwise outer end portion and the longitudinal outer end portion thereof) was 5 μm.

Thereafter, the metal supporting board was trimmed by chemical etching (wet etching) to obtain a suspension board with circuit.

A scanning electron micrograph of a cross section of the obtained suspension board with circuit is shown in FIG. 8.

As shown in FIG. 8, the angle (θ2) between the widthwise outer surface of the insulating cover layer and the widthwise outer surface of the insulating base layer was 150°. The angle (θ1) between the widthwise outer surface of the insulating base layer and the lower surface thereof was 45°.

In the obtained suspension board with circuit, delamination between the insulating cover layer and the insulating base layer was not observed.

While the illustrative embodiments of the present invention are provided in the above description, such is for illustrative purpose only and it is not to be construed limitative. Modification and variation of the present invention which will be obvious to those skilled in the art is to be covered by the following claims.

What is claimed is:

1. A wired circuit board, comprising:
a first insulating layer;
a conductive pattern formed on a surface of the first insulating layer at one side in a thickness direction; and
a second insulating layer formed on the surface of the first insulating layer at the one side in the thickness direction so as to cover the conductive pattern, wherein
an outer end surface of the first insulating layer in a perpendicular direction which is perpendicular to the thickness direction is formed to be inclined outwardly in the perpendicular direction gradually from the one side in the thickness direction toward the other side in the thickness direction, and
an outer end surface of the second insulating layer in the perpendicular direction has an end edge at the other side in the thickness direction which is located between both end edges of the outer end surface of the first insulating layer in the perpendicular direction which are located at the one side and the other side in the thickness direction.

2. A wired circuit board according to claim 1, wherein the outer end surface of the second insulating layer in the perpendicular direction is formed to be inclined outwardly in the perpendicular direction gradually from the one side in the thickness direction toward the other side in the thickness direction.

3. A wired circuit board according to claim 1, wherein an obtuse angle formed between the outer end surface of the first insulating layer in the perpendicular direction and the outer end surface of the second insulating layer in the perpendicular direction is more than 120° and less than 180°.

4. A wired circuit board according to claim 1, wherein an acute angle formed between an end surface of the first insulating layer at the other side in the thickness direction and the outer end surface of the first insulating layer in the perpendicular direction is not less than 20° and not more than 70°.
